(19) United States
(12) Patent Application Publication
(10) Pub. No.: US 2026/0239637 A1
(43) Pub. Date: Aug. 13, 2026

(54) METAL-INSULATOR-METAL CAPACITOR WITH MULTI-ELECTRODE & DOUBLE SIDE DEPOSITION

(71) Applicant: Taiwan Semiconductor Manufacturing Company, Ltd., Hsinchu (TW)

(72) Inventors: Jaio-Wei Wang, Kaohsiung City (TW); Meng-Hsien Lin, Tainan City (TW); Jen-Cheng Liu, Hsin-Chu City (TW); Hsing-Chih Lin, Tainan City (TW); Shih-Rong Yang, Hsinchu (TW)

(21) Appl. No.: 19/214,315

(22) Filed: May 21, 2025

Related U.S. Application Data
(60) Provisional application No. 63/757,891, filed on Feb. 13, 2025.

(51) Int. Cl. H10D 1/68; H01L 23/522; H10D 1/00

(52) U.S. Cl. CPC H10D 1/716; H10D 1/042; H10W 20/496

(57) ABSTRACT

Some embodiments relate to a device including a semiconductor substrate, and an interconnect structure disposed over the semiconductor substrate. The interconnect structure includes a lower metal line, an intermediate metal line, and an upper metal line, and a plurality of metal vias. A first electrode disposed in the interconnect structure includes a first lateral portion and a protrusion that extends downward from the first lateral portion. The first lateral portion is disposed over an upper surface of the upper metal line, and the protrusion extends below a lower surface of the lower metal line. A second electrode is disposed in the interconnect structure, matingly engages the first electrode, and has a lower surface that is below a lower surface of the first electrode. A dielectric laterally surrounds an inner sidewall structure of the second electrode to separate the second electrode from an outer sidewall structure of the first electrode.

### REFERENCE TO RELATED APPLICATION

This Application claims the benefit of U.S. Provisional Application No. 63/757,891, filed on Feb. 13, 2025, the contents of which are hereby incorporated by reference in their entirety.

### BACKGROUND

Capacitors are a passive circuit component used in imaging, memory, and many more applications. One common type of capacitor in integrated circuits is a metal-insulator-metal (MIM) capacitor. A MIM capacitor has a metal bottom layer, a metal top layer, and a dielectric layer separating the metal bottom layer from the metal top layer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of a device including a MIM capacitor in accordance with some embodiments.

FIG. 2A illustrates a top view of some embodiments of the capacitor of FIG. 1 in accordance with some embodiments.

FIG. 2B illustrates a perspective exploded view of some embodiments of the MIM capacitor of FIG. 1 and FIG. 2A in accordance with some embodiments.

FIG. 2C illustrates a perspective exploded view of some embodiments of the MIM capacitor in accordance with some other embodiments.

FIG. 3 illustrates a cross-sectional view of some embodiments of a device including a MIM capacitor in accordance with some embodiments.

FIG. 4 illustrates a top view of some embodiments of the capacitor of FIG. 3 in accordance with some embodiments.

FIG. 5 illustrates a cross-sectional view of some embodiments of a device including a MIM capacitor in accordance with some embodiments.

FIG. 6 illustrates a top view of some embodiments of the capacitor of FIG. 5 in accordance with some embodiments.

FIGS. 7-12 illustrate various alternative top views of the capacitor of FIG. 1, FIG. 3, or FIG. 5 in accordance with some embodiments.

FIGS. 13A-13B, 14A-14B, 15A-15B, 16A-16B, 17A-17B, and 18 illustrate a series of cross-sectional views (FIGS. 13A, 14A, 15A, 16A, 17A, 18) and top views (FIGS. 13B, 14B, 15B, 16B, 17B) that collectively illustrate a manufacturing flow for making a capacitor in accordance with some embodiments.

FIG. 19A illustrates a cross-sectional view and FIGS. 19B and 20 illustrate a series of top views that illustrate an alternative manufacturing flow that follow from FIG. 15A-15B or 16A-16B in accordance with some embodiments.

FIG. 21 illustrates a flowchart of some embodiments of a method of forming a device including a MIM capacitor.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A MIM capacitor includes a lower metal layer, an upper metal layer, and a capacitor dielectric separating the lower metal layer from the upper metal layer. The MIM capacitor may extend horizontally across an interlayer dielectric (ILD) layer, and vertically through the ILD layer. The present disclosure provides MIM capacitors that have an increased surface area between the lower metal layer and upper metal layer to provide an increased capacitance compared to previous approaches. Some embodiments of the present disclosure have a lower electrode with a central region and a peripheral region laterally surrounding the central region. The central region of the lower electrode includes a series of openings. The upper electrode includes a plurality of tubes or pillars and a valley structure that laterally surrounds the tubes or pillars. The tubes or pillars of the second electrode matingly engage the openings in the central region of the first electrode, and the valley structure of the second electrode matingly engages a trench in the first electrode, wherein the trench separates the central region of the lower electrode from the peripheral region of the lower electrode. The mating engagement of the trench and valley structure helps to prevent etching defects that can occur in previous approaches, and thereby offers more reliable devices than previous approaches.

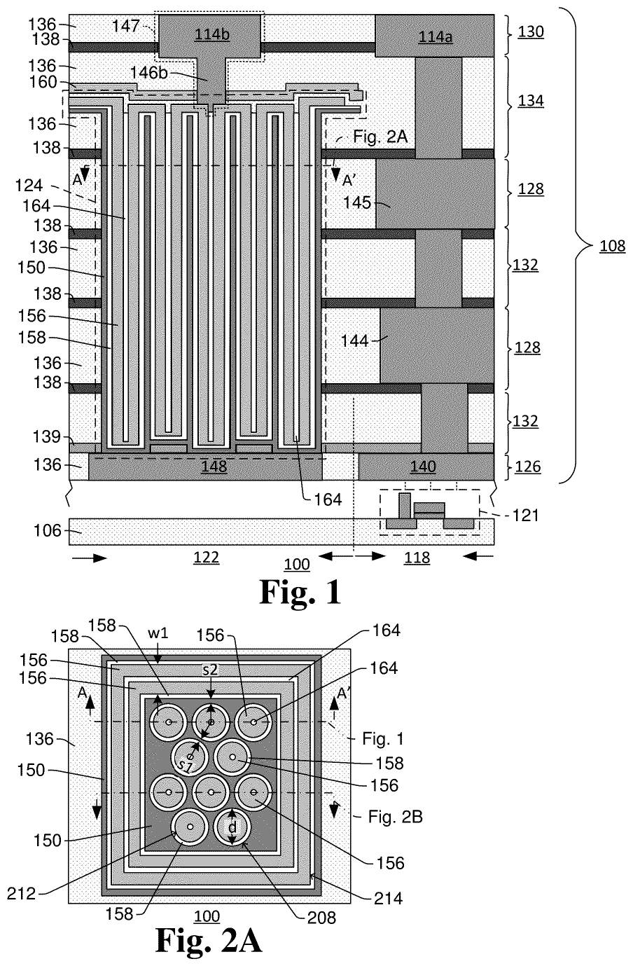

FIG. 1 illustrates a cross-sectional view of some embodiments of a device 100 including a MIM capacitor 124 according to some embodiments. The device 100 includes a semiconductor substrate 106 and an interconnect structure 108 over the semiconductor substrate 106. The semiconductor substrate 106 includes a capacitor region 122, which in some examples can be devoid of semiconductor devices in the substrate. The semiconductor substrate 106 can also include a logic region 118 that includes semiconductor devices (e.g., transistor 121) that are connected to one another by conductive features in the interconnect structure 108. In general, the interconnect structure 108 includes a number of metal line/pad layers (e.g., 126, 128, 130) and via layers (e.g., 132, 134) arranged within an inter-layer dielectric (ILD) structure 136. The metal line layers can include a lower metal layer 126 (e.g., lower metal features 140, 148), one or more intermediate metal layer(s) (e.g., intermediate metal features 144, 145), and an upper metal layer (e.g., upper metal features/pads 114a, 114b). Etch stop layers 138, 139 are disposed at the top and/or bottom of the various metal line layers and/or via layers. In some embodiments, the semiconductor devices include a transistor device 121 (e.g., a planar field effect transistor (FET), a FinFET, a gate-all-around (GAA) device, bi-polar junction transistor (BJT)), but could also include diodes, etc.

Within the capacitor region 122, the interconnect structure 108 includes lower metal feature 148 and upper metal feature 147, which includes upper via 146b and upper metal line 114b. The upper metal feature 147 is disposed over the lower metal feature 148. In some embodiments, the upper metal feature 147 and the lower metal feature are nearest metal layers to one another, but more often there are additional metal layers (e.g., 128) between the upper metal feature 147 and the lower metal feature 148.

The MIM capacitor 124 includes a first electrode 150 coupled to the lower metal feature 148, and a second electrode 156 coupled to the upper metal feature 147. A capacitor dielectric 158 separates the first electrode 150 from the second electrode 156. In some embodiments, a depth of the first electrode 150 and/or second electrode 156 is greater than the combined height of the lower metal layer 126 and lower via layer 132. Thus, the depth of the first electrode 150 and/or second electrode 156 exceeds a height that separates two, three, four, five, six, seven, or an even greater number of etch stop layers 138. Further, in some embodiments, the depth of the first and/or second electrode can be between 1.5 micrometers and 2.0 micrometers. In other cases, the depth of the first electrode 150 and/or second electrode 156 can be between 3 micrometers and 4 micrometers. Because this depth is greater than previous MIM capacitors, the MIM capacitor 124 of FIG. 1 can provide an increased capacitance compared with previous capacitors.

In some embodiments, the first electrode 150 and second electrode 156 are made of the same material as one another. For example, the first electrode 150 and second electrode 156 can comprise titanium or tantalum. Although not illustrated in FIG. 1, in some examples the first electrode 150 includes a barrier layer disposed along inner sidewalls of a recess in which the MIM capacitor is formed, and a first capacitor bottom electrode layer along inner sidewalls of the barrier layer. The barrier layer can be or comprise tantalum or tantalum nitride. The first capacitor bottom electrode layer can be or comprise titanium nitride.

The capacitor dielectric 158 is arranged along the sidewalls of the first electrode and/or second electrode. The capacitor dielectric 158 can be silicon dioxide or a high-k dielectric material. A dielectric 164, such as silicon dioxide, can be optionally present between innermost sidewalls of upwardly facing portions of the second electrode 156. A dielectric capping structure 160, which can be a hard mask such as silicon nitride, can cover an upper surface of the second electrode 156. The via 146b extends down from the upper metal line 114b (or bond pad) to the second electrode 156 and extends through the dielectric capping structure 160.

In some examples, the lower etch stop layer 139 has a different composition than the upper etch stop layers 138. This can enable the upper etch stop layers 138 to have an etching rate similar to the material of the second electrode 156 for a predetermined etch, while the lower etch stop layer 139 can have an etching rate different from the material of the second electrode for the predetermined etch.

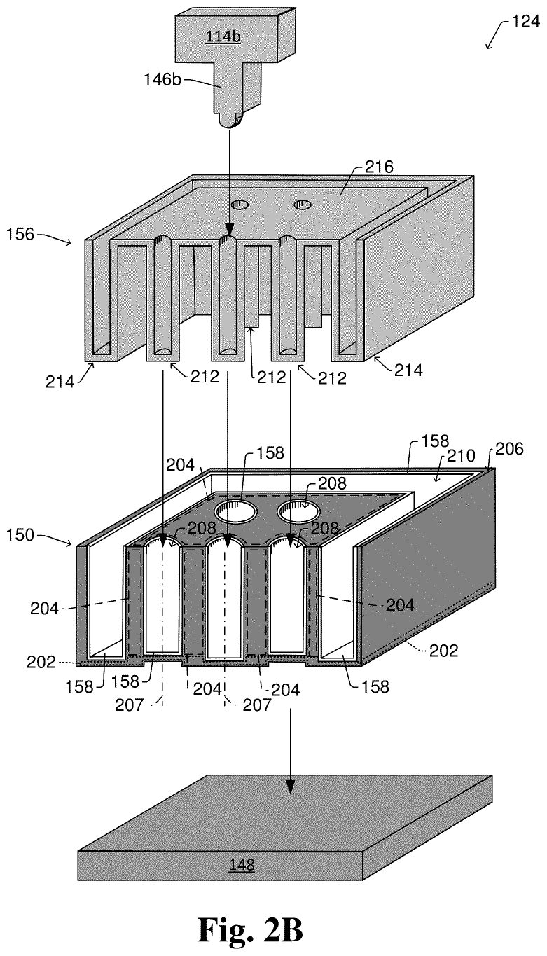

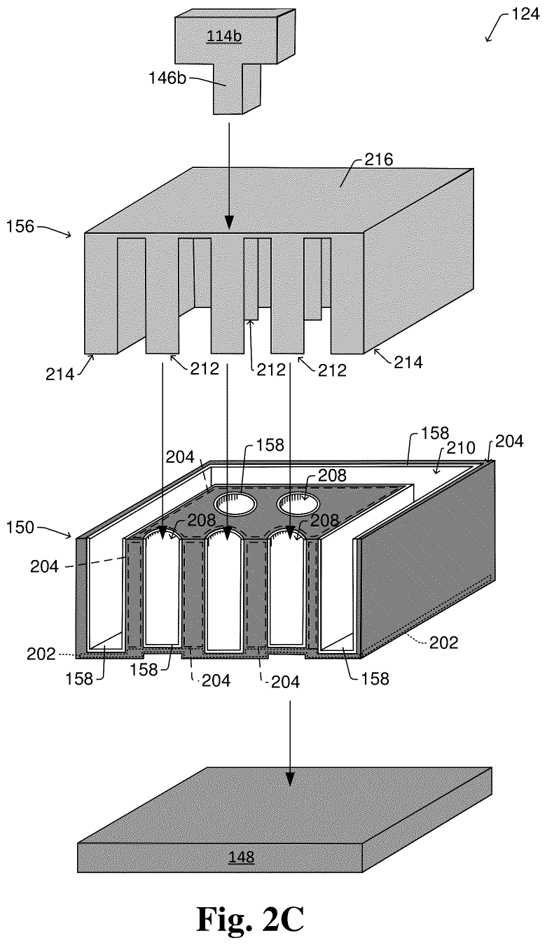

FIG. 2A illustrates a top view consistent with FIG. 1's device 100 and FIG. 2B illustrates a perspective exploded view consistent with portions of the device 100. FIG. 2B illustrates lower conductive feature 148, first electrode 150, second electrode 156, capacitor dielectric 158, and upper conductive feature 114b/146b, and is now described concurrently with FIG. 2A. The first electrode 150 includes a base portion 202 disposed on an upper surface of the lower metal feature 148. The first electrode 150 also includes a central portion 204 extending upward from a central region of the base portion 202, and a peripheral portion 206 extending up from a peripheral portion of the base portion 202. The central portion 204 of the first electrode includes a plurality of openings 208 and is laterally surrounded by the peripheral portion 206 of the first electrode 150. The openings 208 are cylindrical in shape and have respective axes 207 extending in a first direction that is perpendicular to an upper surface of the substrate. A trench structure 210 laterally separates the central portion 204 of the first electrode from the peripheral portion 206 of the first electrode. The openings 208 and trench structure 210 have sidewalls that are lined with the capacitor dielectric 158. In the example of FIGS. 2A-2B, the openings 208 have outer perimeters that are circular when viewed from above, but the openings 208 can also have outer perimeters that are square, square with rounded corners, rectangular, rectangular with rounded corners, oval, other polygonal shape, or other polygonal shape with rounded corners when viewed from a top view. Thus, “cylindrical” as used herein can include any/all of these shapes.

As illustrated in FIG. 2B, the second electrode 156 includes an upper plate 216 with a plurality of tubes 212 that extend downward from the upper plate 216. The tubes 212 matingly engage the openings 208 in the central portion 204 of the first electrode 150. A ring-shaped valley structure 214 laterally surrounds the plurality of tubes 212 and laterally surrounds the central portion 204 of the first electrode 150. The tubes 212 typically are disposed within the openings 208 and are geometrically similar to the openings 208. Thus, in the example of FIGS. 2A-2B, the tubes 212 have outer perimeters that are circular when viewed from above, but the tubes 212 can also have outer perimeters that are square, square with rounded corners, rectangular, rectangular with rounded corners, oval, other polygonal shape, or other polygonal shape with rounded corners when viewed from a top view.

As illustrated in FIG. 2A, the openings 208 in the central portion of the first electrode have a diameter (d) or width that is greater than 0.08 micrometers and less than 0.2 micrometers. The ring-shaped valley structure 214 can also have a width w1 between its opposing sidewalls. In some examples, a ratio of width w1:d can range from 0.5:1 to 2:1. Further, a minimum distance s1 between two neighboring openings 208 can range between 0.08 micrometers to 0.2 micrometers, for example. A minimum distance s2 between an inner edge of the ring-shaped valley structure 214 and an adjacent opening 208 can range from 0.08 micrometers to 0.2 micrometers for example. Thus, in some cases s1 and s2 can be equal, but a ratio of s1:s2 can also range from 0.9:1.1 to 1.1:0.9 in some examples.

FIG. 2C illustrates another example where the second electrode 156 includes a plurality of pillars 212 that are each a solid and/or continuous metal body between outer sidewalls of each pillar, rather than “hollow” pillars 212 as previously illustrated in FIG. 2B. FIG. 2B provides an advantage in that by having dielectric (see FIGS. 1, 164) in the centers of the tubes, the overall hardness of the MIM capacitor 124 is closer to the overall hardness of other areas (e.g., logic are 118) of the integrated circuit, which limits “dishing” when chemical mechanical planarization (CMP) is carried out. In contrast, because the example of FIG. 2C has “solid” metal pillars, the MIM capacitor area of FIG. 2C's device might be “harder” than the logic regions of the device, causing dishing in the logic regions if/when CMP is carried out, but is still a feasible solution in many regards.

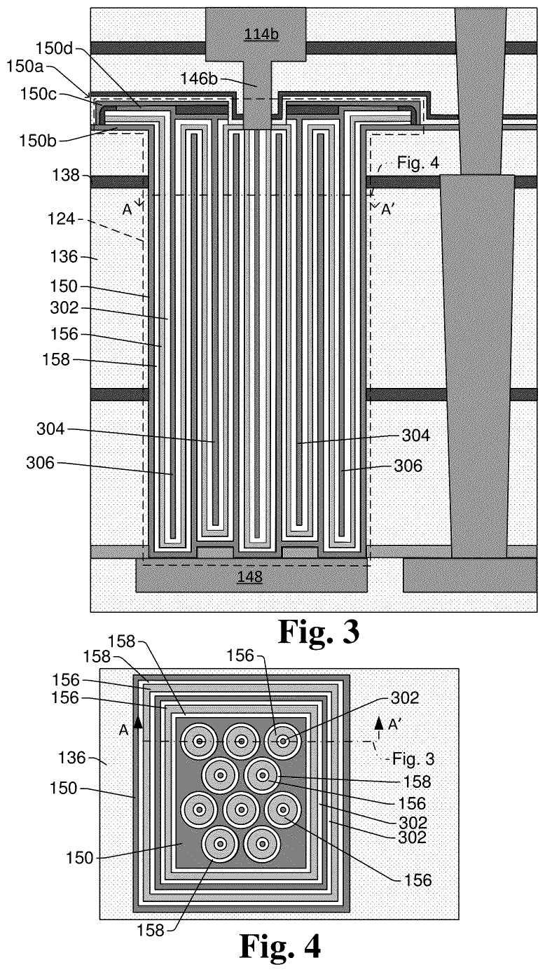

FIG. 3 illustrates a cross-sectional view of a device including another MIM capacitor and FIG. 4 illustrates a top-view consistent with FIG. 3 in accordance with some other embodiments. In this example, the MIM capacitor 124b includes a first capacitor dielectric 158 lining inner sidewalls of the first electrode 150, and second capacitor electrode 156 lines inner sidewalls of the first capacitor dielectric 158. In addition, a second capacitor dielectric 302 lines inner sidewalls of the second capacitor electrode 156 to establish cylindrical openings and a trench structure corresponding to inner sidewalls of the second capacitor dielectric 302. The first electrode 150 also includes an upper portion 150a having pillar shaped protrusions 304 and a ring-shaped valley structure protrusion 306 that extend downward along the sidewalls of the second capacitor dielectric 302. In particular, the upper portion of the first electrode includes a lip 150b, and a conductive capping structure 150c that extends up from the lip 150b, and over an edge of the first and second capacitor dielectrics 158, 302 and over and edge of the second capacitor electrode 156 to adjoin a lateral portion 150d of the upper portion of the first electrode. In some embodiments, the first and second capacitor dielectrics 158, 302 are made of the same material, such as silicon dioxide or a high-k dielectric. However, in other embodiments the first capacitor dielectric 158 is a first dielectric material and the second capacitor dielectric 302 is a second dielectric material, which can be helpful when integrating various types of devices in one process flow. Thus, the MIM capacitor of FIGS. 3-4 is a “double-sided” capacitor because a lowermost, outermost portion of the first electrode 150, first capacitor dielectric 158, and second capacitor electrode 156 define a first capacitance; while the upper portion of the first electrode 150a and protrusions 304, 306, second capacitor dielectric 302, and second capacitor electrode 156 define a second capacitance that is in parallel with the first capacitance. Thus, FIG. 3-4's MIM capacitor 124 has an increased capacitance in a given footprint compared to previous implementations.

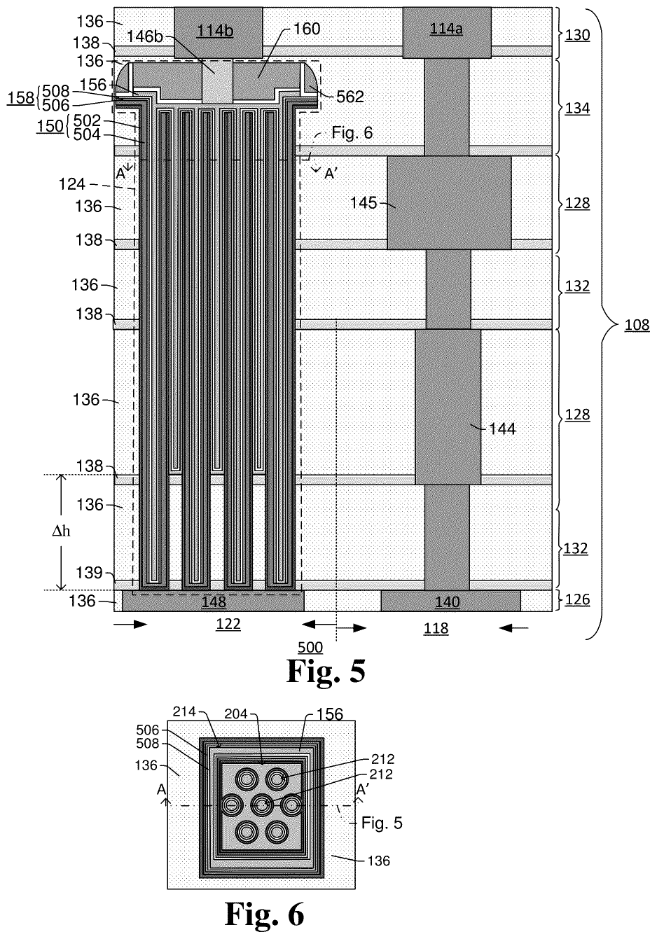

FIG. 5 illustrates a cross-sectional view of a device 500 including another MIM capacitor and FIG. 6 illustrates a top-view consistent with FIG. 5 in accordance with some other embodiments. Compared to the example of FIGS. 1, 2A, and 2B in which the central portion 204 of the first electrode 150 has substantially the same height/depth as the tubes/pillars 212 and valley structure 214 (e.g., the height of the first electrode is within 10%, within 5%, within 2%, or even within 1% of the height of the tubes/pillars), in FIG. 5-6's example the central portion 204 of the first electrode 150 has a different height/length from the tubes/pillars 212 and valley structure 214 (see height difference, Δh). In FIGS. 5-6, this height difference Δh is a distance between nearest neighboring etch stop layers 138, 139, but in other cases the difference is height Δh can span multiple etch stop layers. Thus, the tubes 212 extend from the via 146b of the second metal feature 147 down to the first metal feature 148, while the central portion 204 of the first electrode 150 stops on etch stop layer 138. Further, compared to the example of FIG. 1, the first electrode 150 includes a barrier layer 502 disposed along inner sidewalls of a recess in which the MIM capacitor is formed, and a first capacitor bottom electrode layer 504 along inner sidewalls of the barrier layer. The barrier layer 502 can be or comprise tantalum or tantalum nitride. The first capacitor bottom electrode layer 504 can be or comprise titanium nitride. Further still, the capacitor dielectric 158 in this example includes a first dielectric layer 506 and a second dielectric layer 508. The first dielectric layer 506 can be a different dielectric material from the second dielectric layer 508. A hardmask layer 160 can also be present, and sidewall spacers 562, which can be made of silicon nitride for example, can also be present along outer sidewalls of the hardmask layer 160.

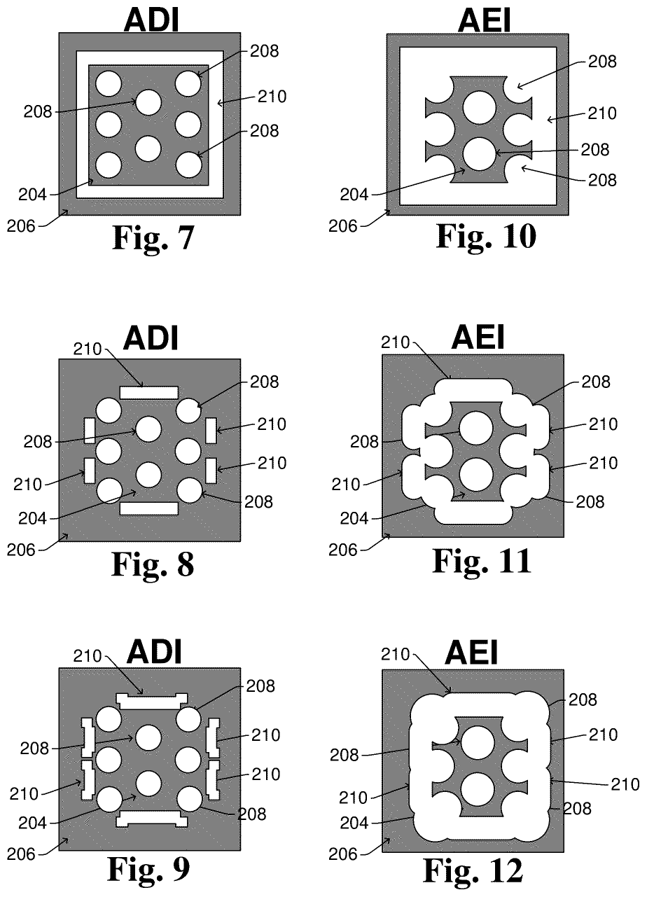

FIGS. 7-12 illustrate various top views illustrating the central portion of the first electrode and the peripheral portion of the first electrode laterally surrounding the central portion of the first electrode. Again, openings 208 are present in the central portion of the first electrode, and a trench structure 210 laterally surrounds the central portion of the first electrode. For purposes of clarity, the capacitor dielectric and the second capacitor electrode are omitted from these figures, but it will be appreciated that these could be present similar to as described elsewhere in this application. Thus, although the trench structure 210 in previously illustrated and described embodiments was shown as a continuous, unbroken ring-like structure laterally surrounding a central portion of the first electrode, the trench structure 210 can also be as shown in FIGS. 7-12 in alternative embodiments.

In FIGS. 7, 8, and 9, the top views illustrate an intermediate manufacturing stage of the structure immediately after photoresist has been exposed and developed but before an etch is carried out (so called after develop inspection (ADI). In contrast, in FIGS. 10, 11, and 12, the top views illustrate a stage of the structure after an etch has been carried out on the structures (so called after etch inspection (AEI)) for FIGS. 7, 8, and 9, respectively.

Thus, FIG. 7 and FIG. 10 show an example whereby the trench structure (e.g., 210 of FIG. 2B) is a ring-shaped structure that laterally surrounds the central region of the first electrode and openings. The ring-shaped structure has a square or rectangular shape as viewed from the top view, and extends in a continuous and un-broken fashion with a constant width between its sidewalls. In some examples, the spacing between an inner sidewall of the trench structure and the nearest openings is no more than 70 nanometers.

FIG. 8 and FIG. 11 show another example whereby the trench structure (e.g., 210 of FIG. 2B) is again a ring-shaped structure that laterally surrounds the central region of the first electrode and openings. Here, however, the ring-shaped structure includes a series of discrete linear segments that follow a square or rectangular shape with a constant width between its sidewalls as viewed from the top view, but are discontinuous with the linear segments having ends when getting within a predetermined distance of the openings. In some examples, the spacing between the ends of two linear segments is not more than 70 nanometers, and the minimum spacing between a linear segment and an adjacent opening is no more than 70 nanometers.

FIG. 9 and FIG. 12 show another example whereby the trench structure (e.g., 210 of FIG. 2B) is again a ring-shaped structure that laterally surrounds the central region of the first electrode and openings, much like FIG. 8 and FIG. 11. Here, however, the discrete linear segments have a serif shape, meaning that a short line is regularly attached to the ends of the linear segments. The serif features are put on a mask to try to help get a desired shape by use of optical proximity correction (OPC) techniques. In other cases, corner rounding can potentially occur for metal lines. To minimize corner rounding, hammer heads can also be added on the end of the lines.

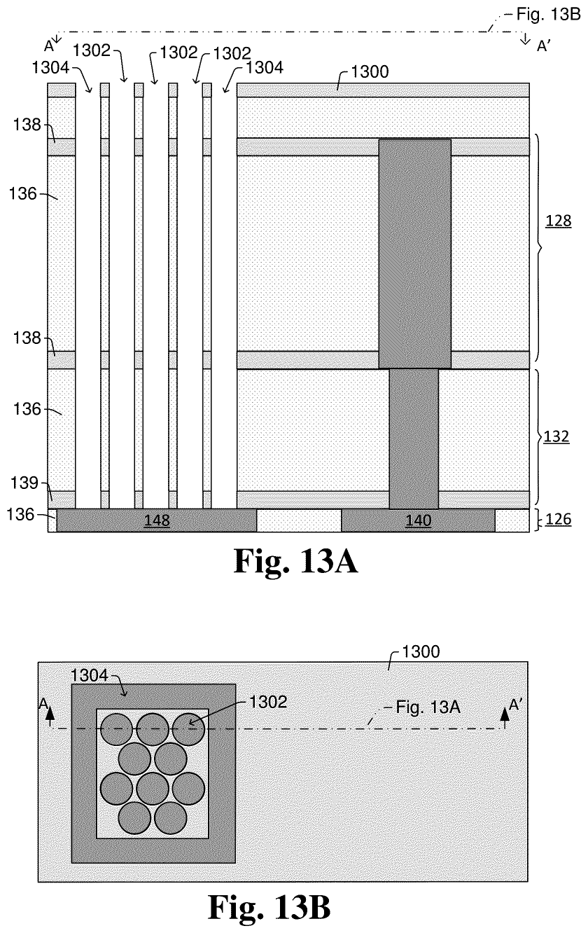

FIGS. 13A-13B through 18 illustrate a series of cross-sectional views (FIGS. 10A-18) and corresponding top views (FIGS. 10B-17B) that collectively illustrate a method of forming a wafer and/or die including a MIM capacitor according to some embodiments. Although these figures are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in FIGS. 13A-13B, an interconnect structure including first and second conductive features 140, 148 are formed within a dielectric structure 130 over the surface of a semiconductor substrate. Although not shown in FIGS. 13A-13B for simplicity, the substrate may be any suitable type of substrate. For example, the substrate may be a semiconductor wafer, one or more dies on a wafer, or any other suitable type of semiconductor body and/or epitaxial layers. In some embodiments, the substrate is or comprises monocrystalline silicon, sapphire, the like, or any combination of the foregoing. The substrate can be a bulk semiconductor substrate or a semiconductor on insulator (SOI) substrate. In some embodiments, the first metal line 140 and a second metal line 148 are or comprise a conductive material, such as copper (Cu), titanium (Ti), aluminum (Al), tungsten, the like, or a combination of the foregoing. In some embodiments, the dielectric structure includes multiple interlayer dielectric layers 136, and various etch stop layers 138, 139. The interlayer dielectric layer 136 is or comprises an insulator, such as a low-k dielectric material, silicon dioxide (SiO₂), or the like. The etch stop layer 138 is or comprises a nitride or carbide, such as silicon nitride (Si₃N₄), silicon carbide (SiC), silicon oxynitride, or the like.

As shown in the cross-sectional view of FIG. 13A, a first masking layer 1300 is formed over the uppermost ILD layer 136. The first masking layer 1300 can be spun-on to the substrate as a liquid, hardened, and then patterned. In some embodiments, the first masking layer 1300 is or comprises a photoresist and/or the first masking layer 1300 is patterned using photolithography. After the first masking layer 1300 is patterned, a first etching process is performed with the first masking layer 1300 in place to form a plurality of MIM capacitor recesses within the ILD structure. The MIM capacitor recesses include openings 1302 and a ring-shaped opening 1304 that laterally surrounds openings 1302. The openings 1302 can be cylindrical openings that have circular perimeters when view from a top view. In other examples, the openings 1302 could be ovals, rectangles, squares, or other polygons, any of which could have rounded corners or square corners when viewed from the top view. After the etch is completed, the first masking layer can be removed, for example by an ashing process or a plasma etching/stripping process.

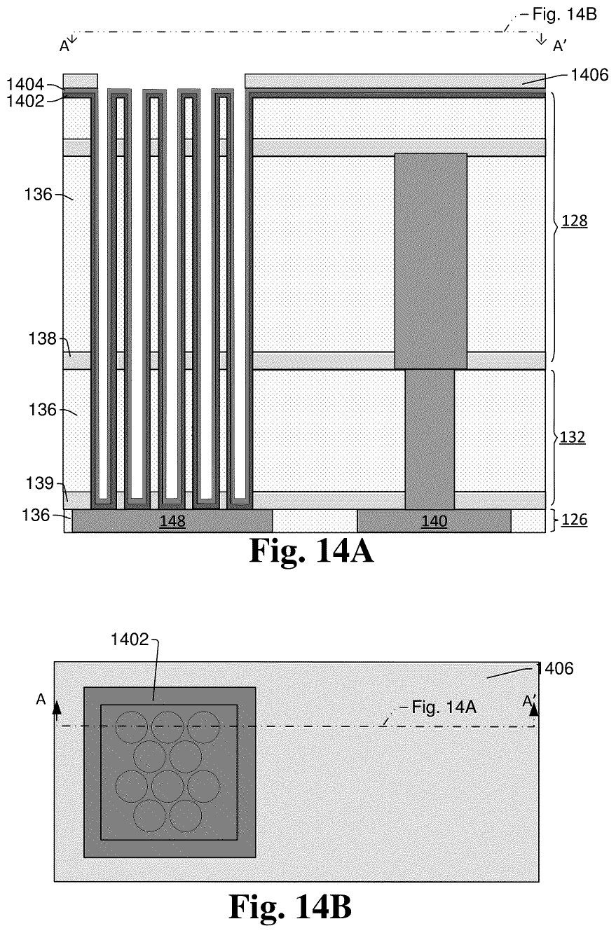

As shown in the cross-sectional and top views of FIGS. 14A-14B, after the openings 1302 and ring-shaped opening 1304 are formed, a barrier layer 1402, such as a tantalum or tantalum nitride layer, is formed along exposed surface of the openings 1302, along exposed surfaces of the ring-shaped opening 1304, and over an upper surface of the ILD layer 136. Thus, the barrier layer 1402 extends over the second conductive feature, and along inner sidewalls of the dielectric structure. A first capacitor bottom metal layer 1404, such as titanium nitride, is then conformally formed over the barrier layer 1402. A second masking layer 1406 is then formed over the structure. The second masking layer 1406 can be spun-on as a liquid, hardened, and then patterned. In some embodiments, the second masking layer 1406 is or comprises a photoresist and/or the second masking layer 1406 is patterned using photolithography.

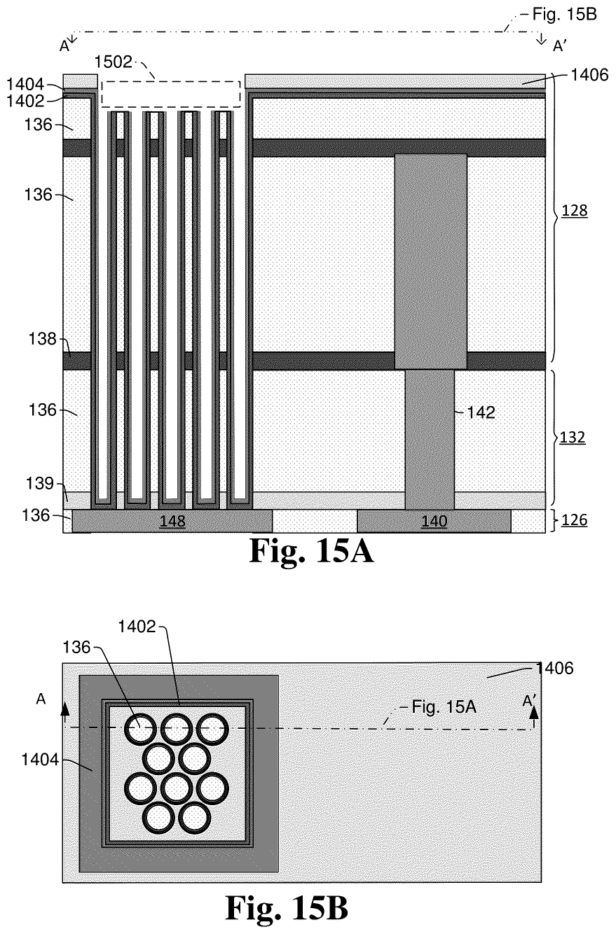

As shown in the cross-sectional and top views of FIGS. 15A-15B, an etch is carried out with the second masking layer 1406 in place. The etch can include a wet etch or a dry etch (e.g., plasma etch) and removes the uppermost extents of the ILD structure left exposed by the second masking layer as well as upper most portions of the first capacitor bottom metal layer 1404 and barrier layer 1402. See 1502. In some cases, the etch can leave the capacitor bottom metal layer 1404 and barrier layer 1402 at the bottom of the trenches in place. After the etch is completed, the second masking layer 1406 can be removed, for example by an ashing process or a plasma etching/stripping process.

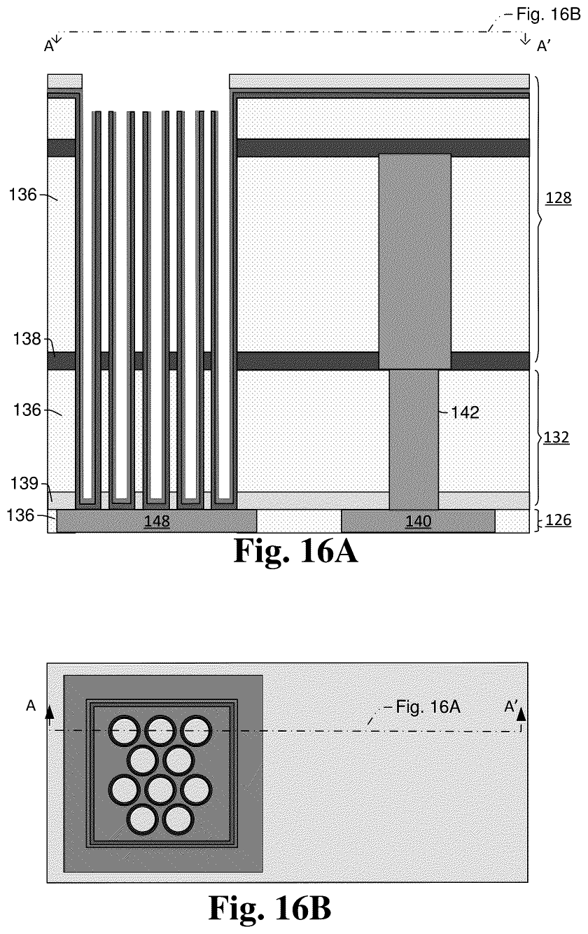

As shown in the cross-sectional and top views of FIGS. 16A-16B, another etch is performed to remove at least some remaining inner portions of the ILD structure from within the openings 1302. For example, a wet using acid, such as hydrofluoric acid, can be used to remove the upper ILD dielectric layers 136, while etch stop layer 138 acts as an etch stop layer.

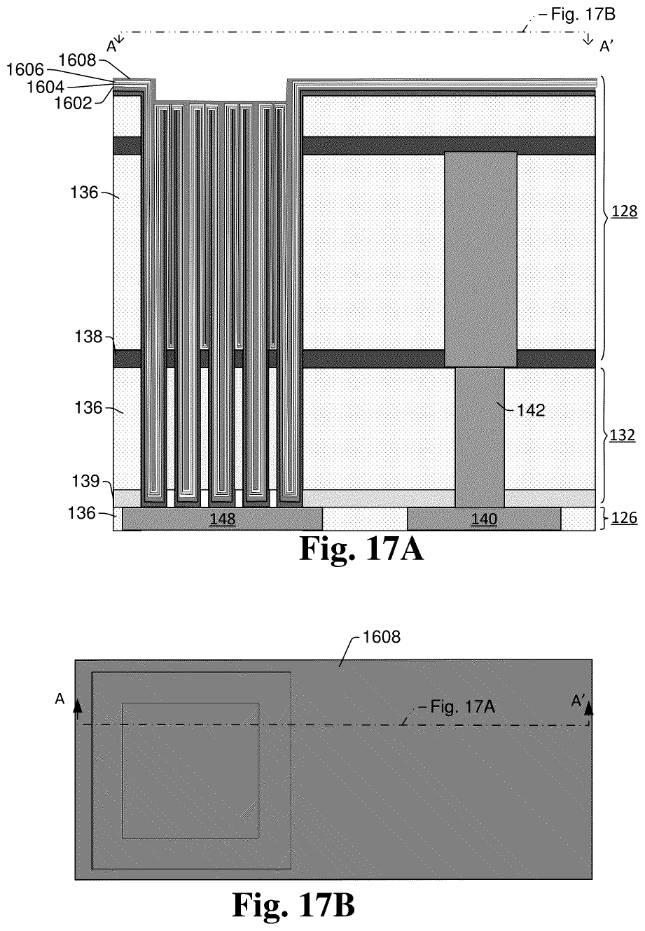

As shown in the cross-sectional and top views of FIGS. 17A-17B, a capacitor dielectric is then formed over the structure. The capacitor dielectric can include a first capacitor dielectric layer 1602 formed conformally within the cylindrical openings and the ring-shaped opening. A second capacitor bottom metal layer 1604, such as titanium nitride, is then conformally formed over the first capacitor dielectric layer 1602 within the recesses. The second capacitor bottom metal layer 1604 can have the same material composition as the first capacitor bottom metal layer 1404, and/or can have a different material composition from the first capacitor bottom metal layer 1404. A second capacitor dielectric layer 1606 is then formed over the second capacitor bottom metal layer 1604, and an upper first electrode metal layer 1608 is then formed over the second capacitor dielectric layer 1606. The upper first electrode metal layer 1608 can have the same material composition as the first capacitor bottom metal layer 1404 and/or second capacitor bottom metal layer 1604. In some examples, the first and/or second capacitor dielectric layers 1602, 1606 is/are a high-K dielectric material, and the second capacitor bottom metal layer 1604 and upper first electrode metal layer 1608 is/are or comprises titanium nitride.

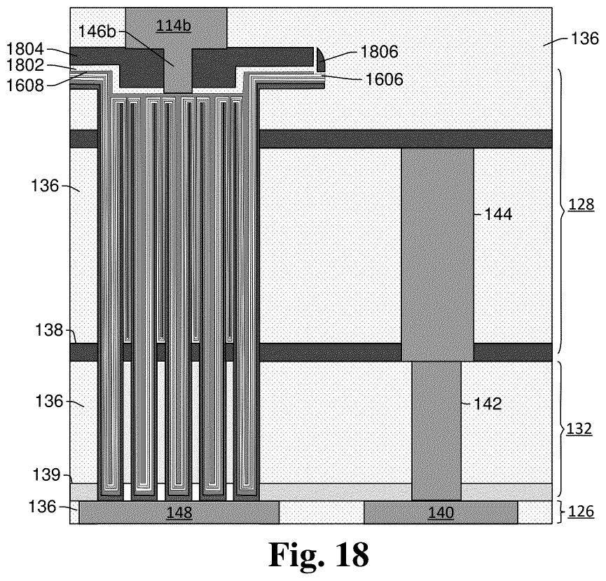

As shown in the cross-sectional view of FIG. 18, a dielectric layer 1802 and hard mask 1804 are formed over the upper first electrode metal layer 1608 and are patterned using photolithography and an etch. A conformal dielectric liner and conformal spacer layer are then formed, and are then etched back to form sidewall spacers 1806 that have lower surfaces that rest on the second capacitor dielectric layer 1606. An inter-layer (ILD) dielectric 136 is then formed over the device, and a via opening is formed through the ILD dielectric, hard mask, and dielectric. A conductive via material is then formed to establish an upper contact/via 146b, and a upper metal line 114b is formed over the upper contact/via.

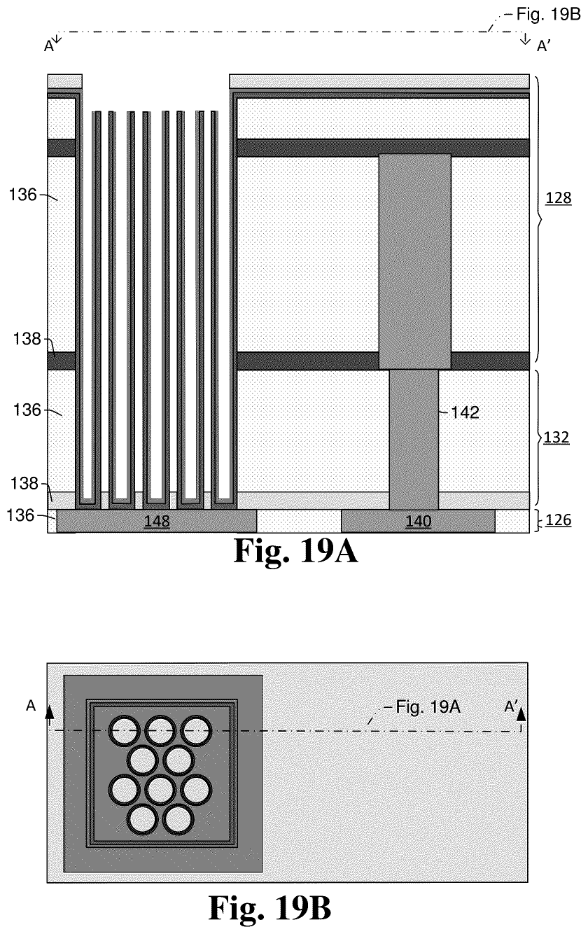

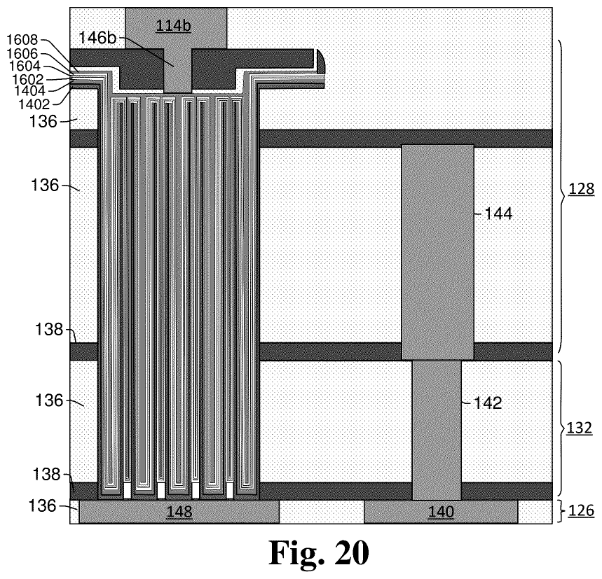

FIGS. 19A-19B and 20 show an alternative embodiment where an additional etch is carried out so the recesses extend all the way through the height of the tubes. So compared to FIG. 16A where the etch stopped on etch stop layer 138, the etch of FIG. 19A-19B removes additional ILD material and etch stop material to continue to until the surface of first capacitor bottom metal layer 1404 the defines the bottom of the recesses is exposed. Then, in FIG. 20 a first capacitor dielectric layer 1602, second capacitor bottom metal layer 1604, a second capacitor dielectric layer 1606, an upper first electrode metal layer 1608, upper contact/via and upper metal line are formed as in FIG. 17A-17B.

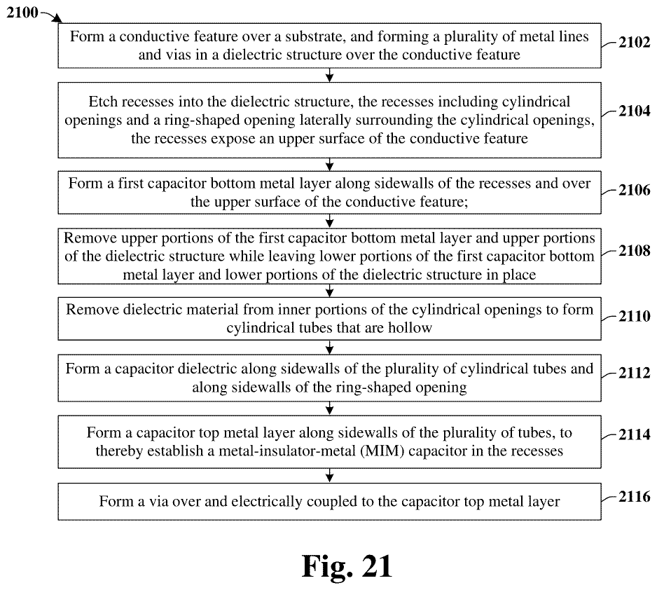

FIG. 21 illustrates a flowchart of some embodiments of a method of forming capacitors with a partial bottom landing on the contact wires. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At 2102, a conductive feature is formed over a substrate. The conductive feature can be a metal line, such as a top metal line in an interconnect structure, or can be a conductive gate or other conductive feature in an interconnect structure over a substrate. A plurality of metal lines and vias are formed in a dielectric structure over the conductive feature. In some embodiments, the conductive feature is formed over a capacitor region of the substrate, and the plurality of metal lines and vias are formed over a logic region of the substrate. See, for example, FIGS. 13A-13B.

At 2104, recesses are etched into the dielectric structure. The recesses include cylindrical openings and a ring-shaped opening laterally surrounding the cylindrical openings. The recesses exposing an upper surface of the conductive feature. See, for example, FIGS. 13A-13B.

At 2106, a first capacitor bottom metal layer is formed along sidewalls of the recesses and over the upper surface of the conductive feature. See, for example, FIGS. 14A-14B.

At 2108, upper portions of the first capacitor bottom metal layer and upper portions of the dielectric structure are removed, while leaving lower portions of the first capacitor bottom metal layer and lower portions of the dielectric structure in place. See, for example, FIGS. 15A-15B.

At 2110, dielectric material is removed from inner portions of the cylindrical openings to form cylindrical tubes that are hollow. See, for example, FIGS. 16A-16B.

At 2112, a capacitor dielectric is formed along sidewalls of the plurality of cylindrical tubes and along sidewalls of the ring-shaped opening. See, for example, FIGS. 17A-17B.

At 2116, a capacitor top metal layer is formed along sidewalls of the plurality of tubes and along sidewalls of the ring-shaped opening, to thereby establish a metal-insulator-metal (MIM) capacitor in the recesses. See, for example, FIGS. 17A-17B.

At 2118, a via is formed over and electrically coupled to the capacitor top metal layer. See, for example, FIG. 18.

Thus, some embodiments relate to a device including a semiconductor substrate, and an interconnect structure disposed over the semiconductor substrate. The interconnect structure includes a lower metal feature and an upper metal feature over the lower metal feature. A first electrode is disposed in the interconnect structure. The first electrode includes a base portion disposed on an upper surface of the lower metal feature, a first peripheral portion extending up from a peripheral portion of the base portion, and a central portion extending upward from a central region of the base portion. The central portion of the first electrode is laterally surrounded by the first peripheral portion of the first electrode. A second electrode is disposed in the interconnect structure over the first electrode and is coupled to the upper metal feature. The second electrode includes a plurality of tubes or pillars that extend into openings in the central portion of the first electrode, and a ring-shaped valley structure that laterally surrounds the plurality of tubes or pillars and that laterally surrounds the central portion of the first electrode. A capacitor dielectric is disposed along outer sidewalls of the plurality of tubes or pillars and along inner sidewalls and outer sidewalls of the ring-shaped valley structure. The capacitor dielectric separates the first electrode from the second electrode.

Other embodiments relate to an integrated circuit including a semiconductor substrate, and an interconnect structure is disposed over the semiconductor substrate. The interconnect structure includes a first metal feature and a second metal feature that are spaced apart in a first direction measured perpendicular to an upper surface of the semiconductor substrate. A first electrode is disposed in the interconnect structure and is coupled to the first metal feature. The first electrode includes a central region and a peripheral region laterally surrounding the central region. The central region includes a series of cylindrical openings having respective axes extending in the first direction. A trench structure laterally surrounds the central region and separates the central region of the first electrode from the peripheral region of the first electrode. A second electrode is disposed in the interconnect structure and coupled to the second metal feature. The second electrode includes a plurality of tubes or pillars that matingly engage the cylindrical openings in the central region of the first electrode and a valley structure that matingly engages the trench structure. A dielectric separates the first electrode from the second electrode.

Still other embodiments relate to a method. In the method, a conductive feature is formed over a substrate, and a plurality of metal lines and vias are formed in a dielectric structure over the conductive feature. Recesses are etched into the dielectric structure. The recesses include a plurality of cylindrical openings and a ring-shaped opening laterally surrounding the cylindrical openings. The recesses extend past the plurality of metal lines and vias and expose an upper surface of the conductive feature. A first capacitor bottom metal layer is formed along sidewalls of the recesses and over the upper surface of the conductive feature. Upper portions of the first capacitor bottom metal layer and upper portions of the dielectric structure are removed, while leaving lower portions of the first capacitor bottom metal layer and lower portions of the dielectric structure in place. Dielectric material is removed from inner portions of the cylindrical openings to form cylindrical tubes that are hollow. A capacitor dielectric is formed along inner sidewalls and outer sidewalls of the cylindrical tubes that are hollow and along sidewalls of the ring-shaped opening. A capacitor top metal layer is formed over the capacitor dielectric along the sidewalls of the cylindrical tubes that are hollow and along the sidewalls of the ring-shaped opening, to thereby establish a metal-insulator-metal (MIM) capacitor in the recesses.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment. Also, in some embodiments, the terms “approximately” and/or “about” can be interpreted as meaning +/−10%, while in other embodiments, the terms “approximately” and/or “about” can be interpreted as meaning within the normal fabrication tolerances of a given fab manufacturing flow.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a semiconductor substrate;
an interconnect structure disposed over the semiconductor substrate, the interconnect structure comprising a lower metal feature and an upper metal feature over the lower metal feature;
a first electrode disposed in the interconnect structure, the first electrode including a base portion disposed on an upper surface of the lower metal feature, a first peripheral portion extending up from a peripheral portion of the base portion, and a central portion extending upward from a central region of the base portion, the central portion of the first electrode laterally surrounded by the first peripheral portion of the first electrode;
a second electrode disposed in the interconnect structure over the first electrode and being coupled to the upper metal feature, the second electrode including a plurality of tubes or pillars that extend into openings in the central portion of the first electrode, and a ring-shaped valley structure that laterally surrounds the plurality of tubes or pillars and that laterally surrounds the central portion of the first electrode; and
a capacitor dielectric disposed along outer sidewalls of the plurality of tubes or pillars and along inner sidewalls and outer sidewalls of the ring-shaped valley structure, the capacitor dielectric separating the first electrode from the second electrode.

2. The device of claim 1, wherein the plurality of tubes or pillars each have an outer perimeter that is circular, square, square with rounded corners, rectangular, oval, or rectangular with rounded corners when viewed from a top view.

3. The device of claim 1, wherein the lower metal feature is a first metal line, and the upper metal feature is a second metal line.

4. The device of claim 3, further comprising at least one additional metal line disposed at a height over the semiconductor substrate, wherein the height of the at least one additional metal line is between a first height of the first metal line and a second height of the second metal line such that the first electrode or second electrode has an overall height that is greater than a minimum height separating nearest metal layers over the semiconductor substrate.

5. The device of claim 1, wherein the openings in the central portion of the first electrode have a diameter or width that is greater than 0.08 micrometers and less than 0.2 micrometers.

6. The device of claim 1, wherein a ratio of a width measured normal to nearest neighboring sidewalls of the ring-shaped valley structure to a width or diameter of an opening of the openings in the central portion of the first electrode ranges between 0.5:1 and 2:1.

7. The device of claim 1, wherein the central region of the first electrode has a first height, and each of the plurality of tubes or pillars have a second height that is within ten percent of the first height.

8. An integrated circuit, comprising:
a semiconductor substrate;
an interconnect structure disposed over the semiconductor substrate, the interconnect structure comprising a first metal feature and a second metal feature that are spaced apart in a first direction measured perpendicular to an upper surface of the semiconductor substrate;
a first electrode disposed in the interconnect structure and coupled to the first metal feature, the first electrode including a central region and a peripheral region laterally surrounding the central region, the central region including a series of cylindrical openings having respective axes extending in the first direction, wherein a trench structure laterally surrounds the central region and separates the central region of the first electrode from the peripheral region of the first electrode;
a second electrode disposed in the interconnect structure coupled to the second metal feature, the second electrode including a plurality of tubes or pillars that matingly engage the cylindrical openings in the central region of the first electrode and a valley structure that matingly engages the trench structure; and
a dielectric that separates the first electrode from the second electrode.

9. The integrated circuit of claim 8, wherein the plurality of tubes or pillars each have an outer perimeter that is circular, square, square with rounded corners, rectangular, or rectangular with rounded corners when viewed from a top view.

10. The integrated circuit of claim 9, wherein the trench structure is rectangular or square when viewed from the top view.

11. The integrated circuit of claim 8, wherein the dielectric is arranged along sidewalls of the tubes or pillars.

12. The integrated circuit of claim 8, wherein the tubes or pillars extend upward past at least three etch stop layers in the interconnect structure.

13. The integrated circuit of claim 8, wherein the central region of the first electrode has a first height, and each of the plurality of tubes or pillars have a second height that differs from the first height.

14. The integrated circuit of claim 13, wherein the trench structure has the first height.

15. The integrated circuit of claim 8, wherein the plurality of tubes or pillars comprise a plurality of tubes, and further comprising:
a dielectric capping structure over an upper surface of the plurality of tubes, and silicon dioxide disposed within the plurality of tubes.

16. The integrated circuit of claim 13, wherein the first metal feature and the second metal feature comprise copper.

17. The integrated circuit of claim 8, wherein the dielectric is a high-k dielectric with a high-k dielectric constant greater than a dielectric constant of silicon.

18. A method, comprising:
forming a conductive feature over a substrate, and forming a plurality of metal lines and vias in a dielectric structure over the conductive feature;
etching recesses into the dielectric structure, the recesses including a plurality of cylindrical openings and a ring-shaped opening laterally surrounding the cylindrical openings, the recesses extending past the plurality of metal lines and vias and exposing an upper surface of the conductive feature;
forming a first capacitor bottom metal layer along sidewalls of the recesses and over the upper surface of the conductive feature;
removing upper portions of the first capacitor bottom metal layer and upper portions of the dielectric structure, while leaving lower portions of the first capacitor bottom metal layer and lower portions of the dielectric structure in place;
removing dielectric material from inner portions of the cylindrical openings to form cylindrical tubes that are hollow;
forming a capacitor dielectric along inner sidewalls and outer sidewalls of the cylindrical tubes that are hollow and along sidewalls of the ring-shaped opening; and
forming a capacitor top metal layer over the capacitor dielectric along the sidewalls of the cylindrical tubes that are hollow and along the sidewalls of the ring-shaped opening, to thereby establish a metal-insulator-metal (MIM) capacitor in the recesses.

19. The method of claim 18, further comprising:
forming a via over and electrically coupled to the capacitor top metal layer.

20. The method of claim 18, wherein forming the capacitor dielectric includes forming a first capacitor dielectric layer and a second capacitor dielectric layer in the recesses, wherein the first capacitor dielectric layer and the second capacitor dielectric layer have different material compositions from one another.
